(19) United States
(12) Patent Application Publication
(10) Pub. No.: US 2006/0040053 A1
(43) Pub. Date: Feb. 23, 2006

(54) Preparation of asymmetric membranes using hot-filament chemical vapor deposition

(75) Inventors: Karen K Gleason, Lexington, MA (US); Richard F Salimaro, Hasting-on Hudson, NY (US)

Correspondence Address: FOLEY HOAG, LLP;PATENT GROUP, WORLD TRADE CENTER WEST, 155 SEAPORT BLVD, BOSTON, MA, 02110, US

(73) Assignee: Massachusetts Institution of Technology, Cambridge, MA (US)

(21) Appl. No.: 10/513,880

(22) PCT Filed: May 9, 2003
(86) PCT No.: PCT/US03/14414

§ 371 Date: Jul. 5, 2005

Related U.S. Application Data
(60) Provisional application No. 60/379,120, filed on May 9, 2002.

(51) Int. Cl. C23C 16/00

(52) U.S. Cl. 427/248.1

(57) ABSTRACT

One aspect of the present invention relates to a method for modifying one side of a PTFE membrane by using HFCVD to deposit a PTFE film on one side of the PTFE membrane. The precursor fluorocarbon gas is preferably hexafluoropropylene oxide, which upon pyrolysis under HFCVD conditions forms reactive CF2 species. The present invention also relates to a modified PTFE membrane having a PTFE film on only one side, wherein the PTFE film has a porosity of greater than about 30% and a dangling bond density of less than about 1018 spins/cm3. The invention further provides a method of filtering a liquid or gas or a mixture of the two, comprising passing the liquid or gas or mixture of the two through the modified PTFE membrane of the present invention.

### BACKGROUND OF THE INVENTION

Porous membrane filters are utilized in a wide variety of environments to separate materials within a fluid stream. The membranes may be formed from a solid polymeric matrix, and have precisely controlled and measurable porosity, pore size and thickness. In use, the membrane filters generally are incorporated into a device, such as a cartridge, which, in turn, is adapted to be inserted within a fluid stream to remove particles, microorganisms or a solute from liquids and gases. Porous membranes are often employed as semi-permeable barriers between two or more miscible fluids. In these applications, the membranes control the transmission of components between the fluids, and in the absence of overriding intermolecular forces, e.g., based on charge, magnetism, and dipoles, they can generally be thought of as acting like sieves. As such, fluid components smaller than pores of the membrane can travel from one membrane surface to the other, but substances larger than the pores cannot. This function is exemplified by the use of membranes as filters to remove particles from liquids or gases.

All membranes are characterized by nominal pore size, which is directly related to the membrane's particle retention characteristics. Pore size is directly proportional and particle retention is inversely proportional to flow rate through the membrane. It is desirable to maximize both particle retention and flow rate. Significantly increasing one of these characteristics while signficantly reducing the other of these characteristics is undesirable.

If a membrane contains a range of pore sizes, the largest pore determines the largest and smallest fluid components that will pass through or be retained by the membrane, respectively. Membranes with maximum pore sizes between about 0.02 μm and about 10 μm (more typically about 1 μm) are referred to as ultrafine. While those with maximum pore sizes smaller than 0.02 μm are considered to be microporous. Such membranes are often used by the electronics and pharmaceutical industries to remove particulate impurities from fluids (i.e., liquids and gases), and for reasons of economics and convenience it is preferred that these filtrations be performed rapidly and reliably. Membrane permeability and strength are therefore properties that are almost as important as pore size.

To be useful, a membrane filter must be resistant to the fluid being filtered so that it maintains its strength, porosity, chemical integrity and cleanliness. For example, in the manufacture of microelectronic circuits, membrane filters are used extensively to purify various process fluids to prevent contaminants from causing circuit failures. Fluid filtration or purification is usually carried out by passing the process fluid through the membrane filter under a differential pressure across the membrane which creates a zone of higher pressure on the upstream side of the membrane. Thus, liquids being filtered in this fashion experience a pressure drop across the membrane filter. This pressure differential also results in the liquid on the upstream side having a higher level of dissolved gases than the liquid on the downstream side. This occurs because gases, such as air, have greater solubility in liquids at higher pressures. As the liquid passes from the upstream side of the membrane filter to the downstream side, dissolved gases come out of solution in the membrane resulting in outgassing of the liquid. Outgassing of a liquid can also occur spontaneously without a pressure differential as long as the liquid contains dissolved gases and there is a driving force for the gases to come out of solution, such as nucleating sites on the surfaces of a membrane where gas pockets can form and grow.

Outgassing liquids typically used in the manufacture of semiconductors and microelectronic devices include very high purity water, ozonated water, organic solvents such as alcohols, and others which are generally significantly chemically active, such as concentrated and aqueous acids or bases which can contain an oxidizer. These chemically active liquids require the use of a chemically inert filter to prevent membrane degradation. Membrane degradation leading to the chemical breakdown of the membrane composition usually results in extractable material which is released from the filter during use, thus compromising the purity, integrity and cleanliness of the fluid being filtered. Fluorocarbon-based membrane filters made from fluorine-containing polymers such as polytetrafluoroethylene are commonly utilized in these applications. Fluorine-containing polymers are well known for their chemical inertness, or excellent resistance to chemical attack. One disadvantage of fluorine-containing polymers is that they are hydrophobic and therefore membranes made from such polymers are difficult to wet with aqueous fluids or other fluids which have surface tensions greater than the surface energy of the membrane.

Another problem often encountered during the filtration of outgassing liquids with a hydrophobic membrane filter is that the membrane provides nucleating sites for dissolved gases to come out of solution under the driving force of the pressure differential, during the filtration process. Gases which come out of solution at these nucleating sites on the hydrophobic membrane surfaces, including the interior pore surfaces and the exterior or geometric surfaces, form gas pockets which adhere to the membrane. As these gas pockets grow in size due to continued outgassing, they begin to displace liquid from the pores of the membrane ultimately reducing the effective filtration area of the membrane. This phenomenon is usually referred to as dewetting of the membrane filter since the fluid-wetted, or fluid-filled portions of the membrane are gradually converted into fluid-nonwetted, or gas-filled portions. Dewetting of a membrane can also occur spontaneously when a wet membrane, such as a hydrophobic membrane wet with an aqueous fluid, is exposed to a gas such as air. It has been found that this dewetting phenomenon occurs more frequently and is more pronounced in fluorocarbon-based membranes made from fluorine-containing polymers such as polytetrafluoroethylene. It has also been found that the rate at which dewetting occurs is greater in small pore size membranes such as 0.2 microns or less, than in larger pore size membranes.

During a filtration process the reduction of effective membrane area available for filtration due to dewetting of the membrane in a filter device results in a reduction of the overall filtration efficiency of the filter. This reduced efficiency manifests itself in a reduction in liquid flow rate through the filter at a given pressure drop or in an increase in pressure drop at a given flow rate. Thus, as the membrane filter dewets with time, the user is not able to purify or filter the same volume of process liquid per unit time as when the filter was newly installed and therefore completely wet. This reduction of the overall throughput capability of the filtration process results in an increase in the user's time and cost to purify a unit volume of process liquid. Faced with a throughput reduction, the user is often required to install new filters in the process and to discard the dewet filters. This premature filter changeout due to dewetting and not necessarily due to the exhaustion of the filter's dirt-holding capacity results in unscheduled downtime and increases the user's overall cost. Optionally, the user can compensate for the reduction in efficiency by making adjustments to other elements of the filtration system such as increasing the speed at which a pump forces liquid through the filter to increase the pressure drop across the membrane, thus maintaining a constant flow rate. These adjustments also translate into higher operating costs for the user and increases the potential for malfunction of the other elements in the system as well as the potential for a process liquid spill due to the increased processing pressures. Another option for the user to avoid premature filter changeout due to dewetting is to treat the filter to rewet the membrane. The treatment is time consuming since it requires that the filter device be removed from the filtration system resulting in unscheduled downtime and can often result in the introduction of contaminants derived from the rewetting process into the process liquid passing through the filter. Typically, a low surface tension rewetting agent may be used, including alcohols such as isopropanol, which are flammable liquids that cause safety concerns. Prior to placing the filtration device back into service, the end user rewets the dewet filter with the alcohol followed by a water flush and then a flush with the process liquid. While membrane manufacturers may have the expertise for handling and treating dewet filters, end users may not have the capabilities or the desire to perform such additional costly processing steps. A number of issued U.S. patents describe surface treatments to alter the wetting characteristics of the membranes. However, no coating process to modify the geometric nature of the pore structure of a PTFE membrane by the deposition of additional PTFE has been disclosed.

U.S. Pat. No. 4,470,859 to Benezra et al, discloses a process for modifying the surfaces of microporous substrates formed of a fluorocarbon such as polytetrafluoroethylene, with a coating of a perfluorocarbon copolymer from a solution of the copolymer to render the surface of the membrane more water wettable. The perfluorocarbon copolymer is dissolved in a solvent at elevated temperature. The membrane then is immersed into the solution which, in turn, is placed into a vacuum chamber. The pressure within the chamber then is reduced such as to approximately 150 millimeters of mercury (absolute) to remove air from within the filter. Thereafter, the pressure within the chamber is quickly returned to atmospheric pressure. This coating process is repeated to ensure, what is described by Benezra et al., complete solution penetration into the pores of the membrane. By proceeding in this manner, the membrane surfaces and the interior walls defining the interstices within the membrane are coated with the perfluorocarbon copolymer. Following the coating step, the solvent is removed by evaporation using heat and vacuum, or the solvated perfluorocarbon copolymer is precipitated with a substance in which the copolymer is effectively insoluble. The solvents utilized to form the solution include halocarbon oil, perfluorooctanoic acid, decafluorobiphenyl, N-butylacetamide, and N,N-dimethylacetamide. Subsequent to modifying the membrane surface, Benezra et al, teaches avoiding the use of a fluid containing a solvent for the modifying copolymer on the membrane surface. Benezra et al. also disclose that alcohol solutions of the copolymer should be avoided.

U.S. Pat. Nos. 4,433,082 and 4,453,991 disclose a process for forming solutions of a perfluorinated ion exchange polymer such as copolymers of tetrafluoroethylene and methyl perfluoro (4,7-dioxa-5-methyl-8-nonenoate) or perfluoro (3,6-dioxa4-methyl-7-octene sulfonyl fluoride) utilizing solvents which are relatively innocuous as compared to the solvents utilized in the coating process set forth above. The perfluorinated ion exchange polymers are dissolved in alcoholic solvents such as isopropanol at elevated temperature and pressure. The solutions obtained are disclosed as being useful in making and repairing films and non-porous membranes used in electrolytic processes such as aqueous sodium chloride electrolysis, in coating substrates such as catalyst supports for use in promoting a wide variety of chemical reactions, for coating porous diaphragms to convert them into non-porous articles and in recovering used perfluorinated polymers having sulfonic acid or sulfonate functional groups for reuse. In electrolytic processes, such as disclosed by these patents, extractables derived from the coated diaphragms are not a substantial concern and the degree of porosity of the modified diaphragm is unimportant.

Solutions of sulfonyl fluoride-containing fluoropolymers are also disclosed in U.S. Pat. No. 4,348,310. The solvents utilized therein are completely halogenated, saturated hydrocarbons, preferably having at least one terminal sulfonyl fluoride polar group. The solutions are disclosed as being used to repair holes in membranes made from fluorinated polymers and for making ion exchange film membranes, dialysis membranes, ultrafiltration and microfiltration membranes. Another disclosed use for these solutions is to coat porous diaphragm for electrochemical cells by contacting a diaphragm with the solution followed by evaporating the halogenated solvent and then hydrolyzing the coated diaphragm to convert the sulfonyl fluoride groups to the acid or salt form.

U.S. Pat. No. 4,902,308 to Mallouk et al, also describes a process for modifying the surface of a porous, expanded polytetrafluoroethylene membrane with a perfluoro-cation exchange polymer from a solution of the polymer. Mallouk et al, also teaches that contact of the surface modified membrane with fluids containing a solvent for the polymer also should be avoided.

U.S. Pat. Nos. 4,259,226 and 4,327,010 disclose modifying a porous membrane surface with a fluorinated polymer having carboxylic acid salt groups. No process steps are disclosed for controlling extractables from the membrane or for controlling the extent of binding of the modifying composition to the membrane surface.

U.S. Pat. Nos. 5,183,545 and 5,094,895 disclose a process for making a multilayer, composite, porous diaphragm from a porous, multilayer, expanded polytetrafluoroethylene substrate having its surface modified with a perfluoro ion exchange polymer composition. The modifying polymer composition can contain a surfactant and may contain excess modifying composition, both of which are sources of undesirable extractables. In addition, these patents disclose a process for coating a thick polyfluorocarbon diaphragm having a thickness exceeding 0.25 mm, preferably between about 0.76 mm and about 5.0 mm with a perfluoro ion exchange polymer. Thin membrane substrates are specifically excluded as is the use of perfluoro ion exchange polymer coatings having an equivalent weight greater than 1000.

U.S. Pat. No. 6,273,271 disclose a process for making a thin porous polymer membrane substrate having its surfaces, including the interior pores surfaces and the exterior, geometric surfaces, completely modified with a deposited and bound perfluorocarbon copolymer composition. Deposition is done in a manner so that the perfluorocarbon copolymer is bound to the polymer substrate surfaces. A solution of the perfluorocarbon copolymer composition is contacted with the thin polymer substrate such as by immersion of the substrate in the solution or by passing the solution through the substrate under pressure or by intruding the membrane proes under pressure. The perfluorocarbon copolymer solution comprises a liquid composition which contains a completely dissolved and/or partially dissolved perfluorocarbon copolymer composition in a solvent, diluent or dispersant medium.

U.S. Pat. No. 6,228,477 discloses a composite membrane and a method of forming a composite membrane where a dispersion of an oleophobic fluoropolymer, such as an acrylic-based polymer with fluorocarbon side chains, and a water-miscible wetting agent wets the surface of the membrane. The wetting agent is removed and the oleophobic fluoropolymer solids in the dispersion are coalesced on the surface without completely blocking the pores.

U.S. Pat. Nos. 5,516,561 and 5,773,098 disclose a method of covalently bonding a microporous PTFE film to make a bilayer for separation by exposing the microporous film to perfluorcyclohexane under plasma conditions. PTFE is disclosed as a substrate upon which the PTFE film is deposited. The methods disclosed are limited to reactive species generation by electromagnetic irradiation, and thus have a greater potential to form PTFE films with higher dangling bond densities (higher densities of single, non-bonded electrons).

Accordingly, it would be desirable to provide thin porous PTFE membranes having on one side a thin PTFE film of low dangling bond density formed via HFCVD methods. In addition, it would be desirable to provide such a membrane with improved wettability characteristics, and which is resistant to chemical attack, such as a porous membrane formed of a fluorine-containing polymer. Furthermore, it would be desirable to provide such a membrane which does not promote nucleation of gases on its surfaces when filtering outgassing liquids such that it does not dewet during use. Also, it would be desirable to provide such a membrane having improved particle retention characteristics as compared to an unmodified membrane without significantly adversely affecting the flux characteristics of the resulting membrane, particularly with small pore size membranes.

### SUMMARY OF THE INVENTION

Asymmetric membranes have been fabricated using hot-filament chemical vapor deposition (HFCVD) to modify one side of a conventional poly(tetrafluoroethylene) (PTFE) membrane. The chemical structure of the modified layer is substantially (>98%) that of PTFE. These asymmetric membranes reduce the pressure drop required for operating separation processes. Thus, less energy must be expended for the filtration of chemicals and solvents and for gas/liquid separations. The asymmetric membranes of the present invention will be useful in the microelectronics industry.

In one aspect, the invention provides a method for modifying one side of a PTFE membrane by using HFCVD to deposit a PTFE film on one side of the PTFE membrane. The precursor fluorocarbon gas is preferably hexafluoropropylene oxide, which upon pyrolysis under HFCVD conditions forms reactive CF₂ species.

Additionally, the invention provides a modified PTFE membrane having a PTFE film on only one side, wherein the PTFE film has a porosity of greater than about 30% and a dangling bond density of less than about 10¹⁸ spins/cm³. The invention further provides a method of filtering a liquid or gas or a mixture of the two, comprising passing the liquid or gas or mixture of the two through the modified PTFE membrane of the present invention. Additionally, a coating process to modify the geometric nature of the pore structure of a PTFE membrane by the deposition of additional PTFE has been discovered. Additional features and advantages of the invention will be apparent from the claims, and from the following detailed description.

### BRIEF DESCRIPTION OF THE FIGURES

FIG. 1 depicts a CVD reactor and a hot filament array used to deposit the polymer films of the present invention on a PTFE membrane.

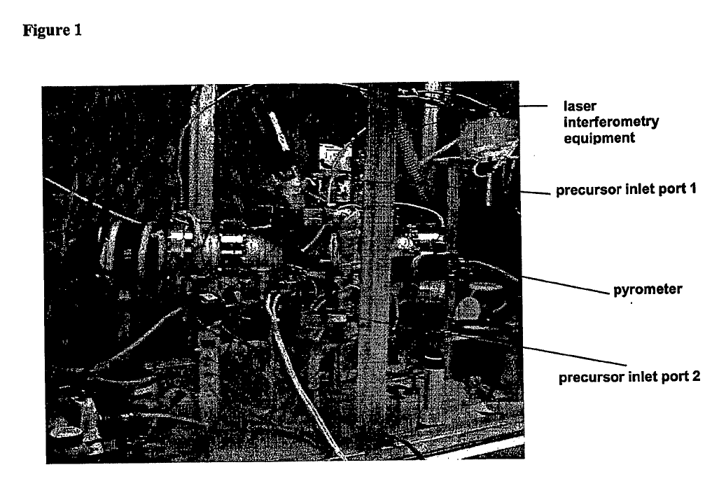

FIG. 2 depicts an SEM image (˜5,000× magnification) of an uncoated PTFE membrane with 0.1 mm pores.

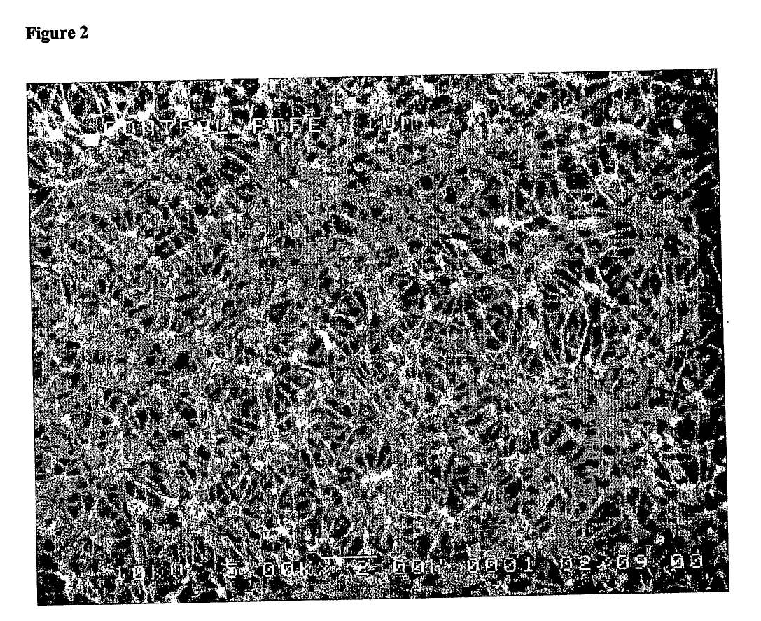

FIG. 3 depicts an SEM image (˜5,000× magnification) of the coated side of a PTFE membrane with 0.1 mm pores, coated with a 20 nm layer of PTFE deposited using HF CVD.

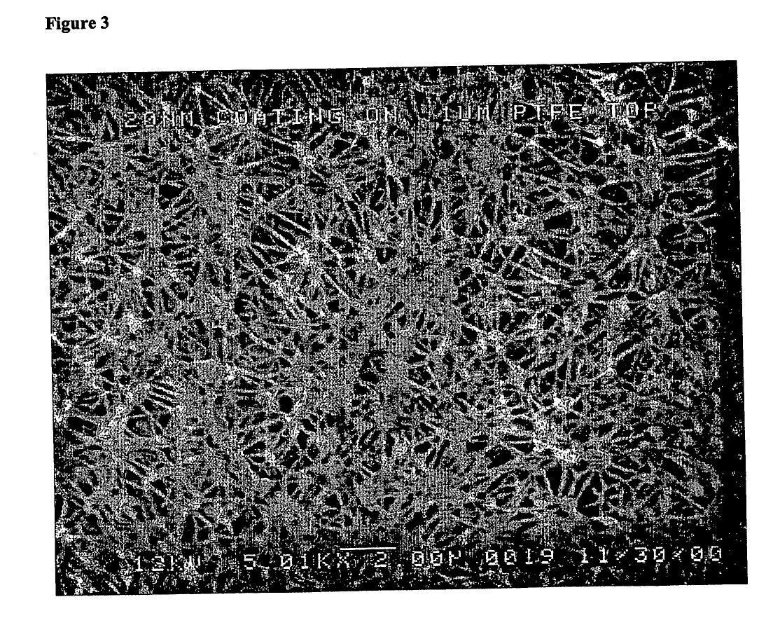

FIG. 4 depicts an SEM image (˜5,000× magnification) of the uncoated side of a PTFE membrane with 0.1 mm pores, coated with a 20 nm layer of PTFE deposited using HF CVD.

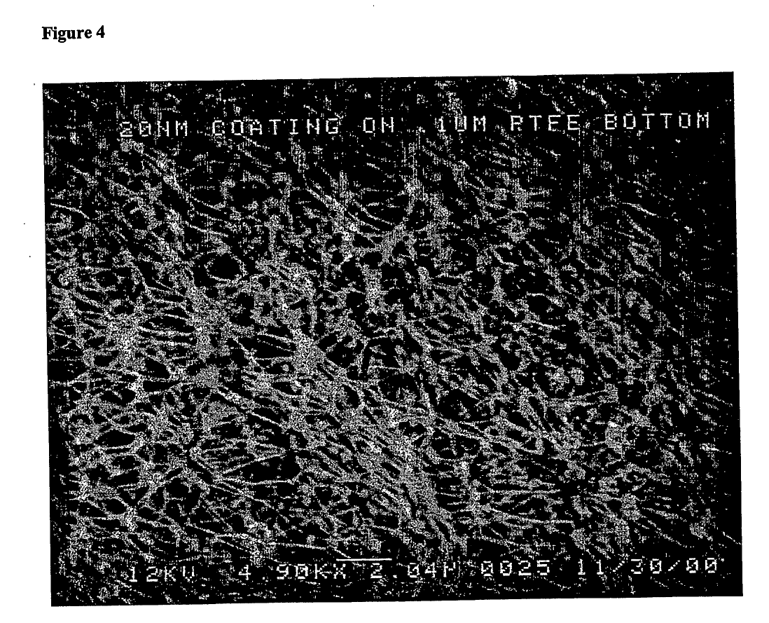

FIG. 5 depicts an SEM image (˜5,000× magnification) of the coated side of a PTFE membrane with 0.1 mm pores, coated with a 100 nm layer of PTFE deposited using HF CVD.

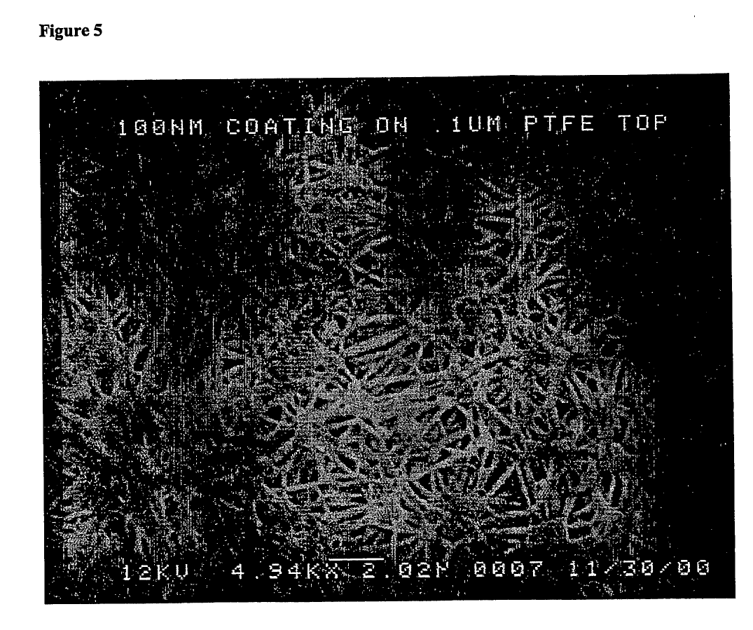

FIG. 6 depicts an SEM image (˜5,000× magnification) of the uncoated side of a PTFE membrane with 0.1 mm pores, coated with a 100 nm layer of PTFE deposited using HF CVD.

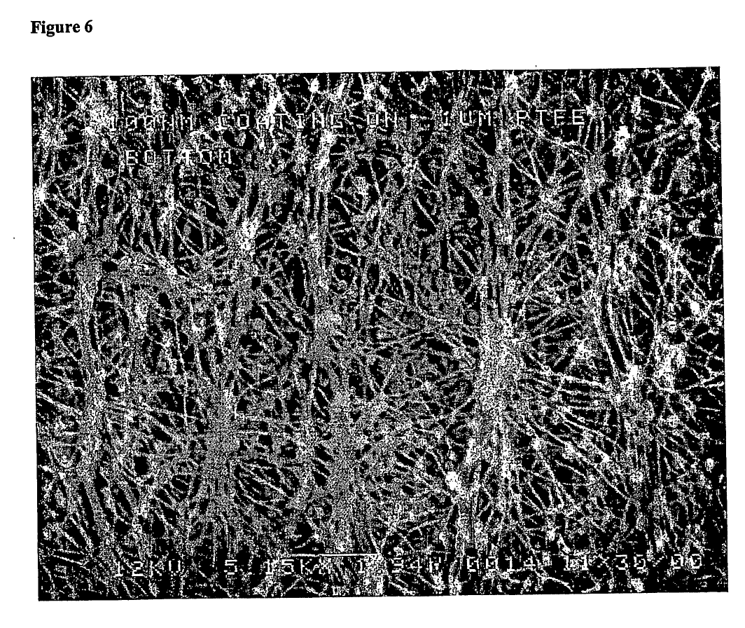

FIG. 7 depicts an SEM image (˜5,000× magnification) of the coated side of a PTFE membrane with 0.1 mm pores, coated with a 300 nm layer of PTFE deposited using HF CVD.

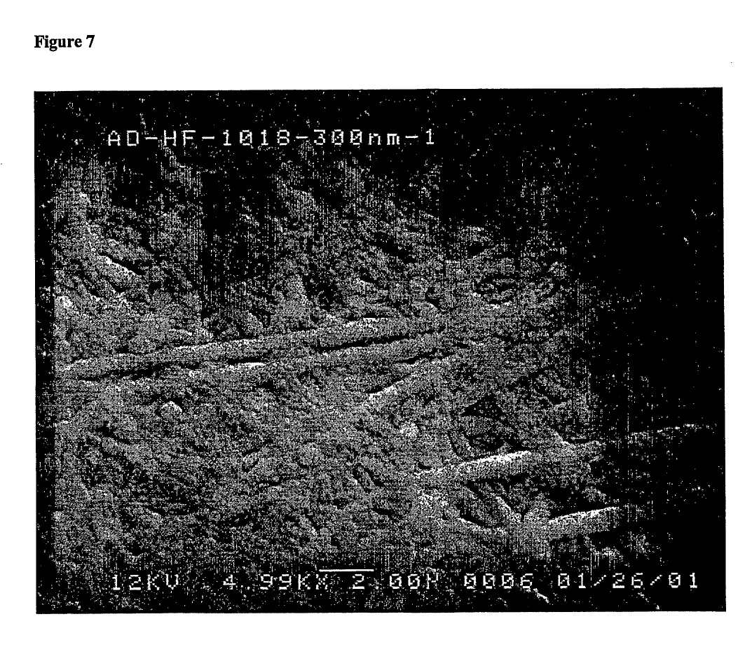

FIG. 8 depicts an SEM image (˜5,000× magnification) of the uncoated side of a PTFE membrane with 0.1 mm pores, coated with a 100 nm layer of PTFE deposited using HF CVD, after soaking in concentrated sulfuric acid for 18 hours.

FIG. 9 depicts an SEM image (˜5,000× magnification) of the coated side of a PTFE membrane with 0.1 mm pores, coated with a 100 nm layer of PTFE deposited using HF CVD, after soaking in concentrated sulfuric acid for 18 hours.

FIG. 10 depicts an SEM image (˜20,000× magnification) of the uncoated side of a PTFE membrane with 0.1 mm pores, coated with a 100 nm layer of PTFE deposited using HF CVD, after soaking in concentrated sulfuric acid for 18 hours.

FIG. 11 depicts an SEM image (˜20,000× magnification) of the coated side of a PTFE membrane with 0.1 mm pores, coated with a 100 nm layer of PTFE deposited using HF CVD, after soaking in concentrated sulfuric acid for 18 hours.

### DETAILED DESCRIPTION OF THE INVENTION

Bulk poly(tetrafluoroethylene), also known as PTFE, (CF₂)ₙ, and Teflon®, is characterized by superior mechanical and electrical properties that are important for a wide range of applications. For example, bulk PTFE is characterized by a low dielectric constant of about 2.1 and a low dielectric loss factor of less than about 0.0003 between about 60 Hz and 30,000 MHz. Bulk PTFE is also characterized by high chemical stability, exemplified by its immunity to even strong alkalis and boiling hydrofluoric acid; low water absorption, exemplified by its water uptake of only about 0.005 weight % in a 24 hour period; and high thermal stability, exemplified by its weight loss of only about 0.05 weight % per hour at about 400° C. A low coefficient of friction of between about 0.05 and about 0.08, and a low permeability constant also characterize bulk PTFE.

There have been proposed various film deposition processes devised with the aim of producing thin films having properties similar to that of bulk PTFE. For example, continuous radio-frequency plasma-enhanced chemical vapor deposition techniques have been proposed for producing PTFE-like films. The films typically produced by such processes have been found, however, to be substantially lacking in one or more critical properties. In particular, the stoichiometry of the resulting films generally differs rather widely from that of bulk PTFE. A typical ratio of fluorine to carbon (F/C ratio) for these films is only about 1.6, whereas bulk PTFE is characterized by a F/C ratio of 2.0. The films produced by various proposed processes are also typically characterized by a low fraction of CF₂ groups; in contrast, bulk PTFE is composed substantially of CF₂ groups. The high degree of crosslinking corresponding to low CF₂ fractionality results in film brittleness, which is unacceptable for applications in which it is desired to encapsulate a flexible, bendable structure in a fluorocarbon film.

Among the different CVD techniques available, hot-filament CVD (HFCVD, also known as pyrolytic or hot-wire CVD) is unique in several respects. In HFCVD, a precursor gas is thermally decomposed by a resistively heated filament. The resulting pyrolysis products adsorb onto a substrate maintained at around room temperature and react to form a film. HFCVD does not require the generation of a plasma, thereby avoiding defects in the growing film produced by UV irradiation and ion bombardment. In addition, films produced by HFCVD have a better-defined chemical structure because there are fewer reaction pathways than in the less selective plasma-enhanced CVD method. HFCVD provides films with a substantially lower density of dangling bonds, i.e. unpaired electrons. Further, HFCVD has been shown to produce films that have a low degree of crosslinking. Limb, S. J., Lau, K. K. S., Edell, D. J., Gleason, E. F., Gleason, K. K. Plasmas and Polymers 1999, 4, 21.

It has recently been shown that HFCVD methods can be used to apply a PTFE film to the surface of a number of substrates useful in the biomedical and microelectronic fields. See U.S. Pat. Nos. 5,888,591; 6,153,269; and 6,156,435; incorporated herein by reference. These substrates include, for example, a neural probe, razor, or silicon wafer. In addition to their high dielectric constant and imperviousness to biological environments, PTFE films also have low permeability. PTFE membranes are used for the filtration of solvents and for gas/liquid separations. The ability to deposit additional layers of PTFE on one side of a PTFE membrane would create an asymmetric filtering system and reduce the pressure drop required for operating such filtering processes. These applications are used by the microelectronics industry but would also be of use in any application that requires highly selective filtrations.

Chemical vapor deposition has the ability to grow films on surfaces of complex topography. Specifically, PTFE films deposited by HFCVD have been demonstrated to adherently coat the porous surfaces of PTFE membranes. The thickness of the HFCVD PTFE layer can be controlled such that the pores become partially or fully closed. The HFCVD layer modifies only the side exposed to the deposition environment, thus creating an asymmetric membrane.

The asymmetry has been directly observed in scanning electron micrographs of the top and bottom surfaces of the membrane. Imaging cross sections created by a focused ion beam reveals that the surface modification by HFCVD penetrates to depth of ten pore diameters or less. Additionally, the flow rates of both air and water are reduced as the thickness of the HFCVD layer increases.

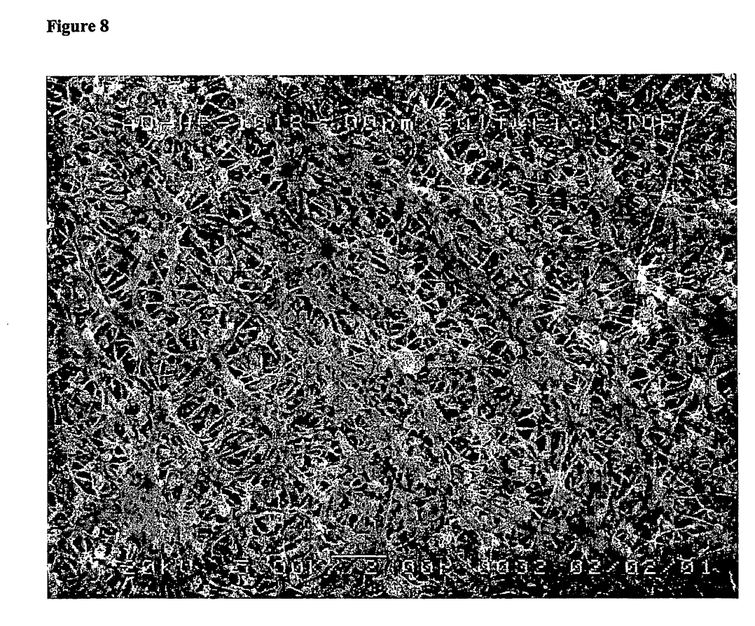

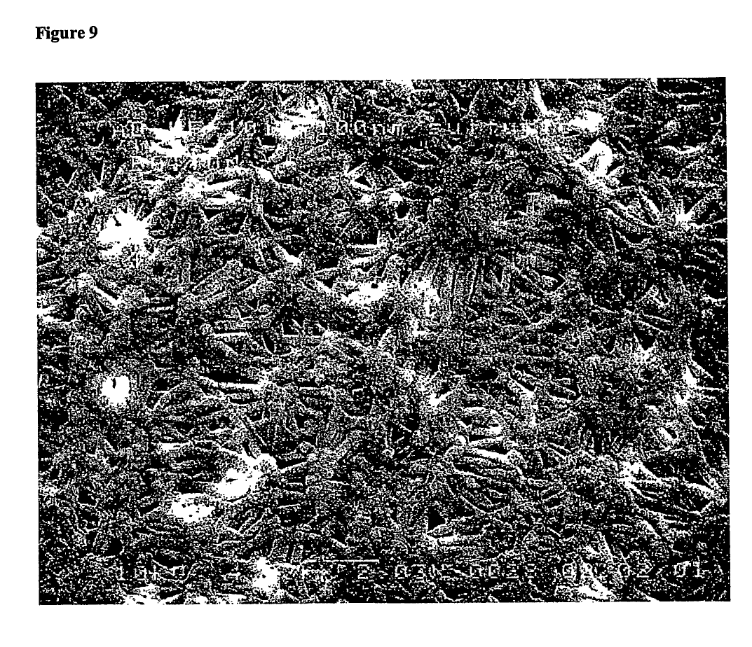

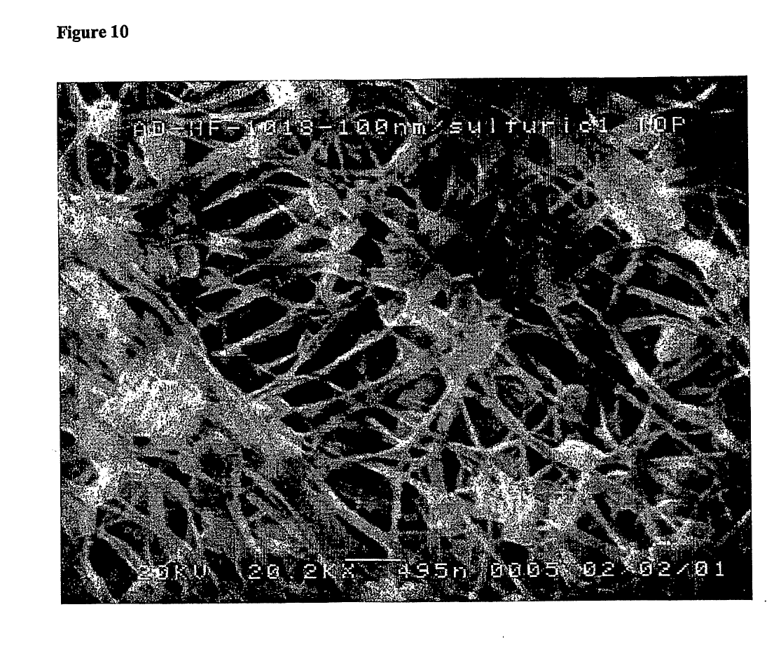

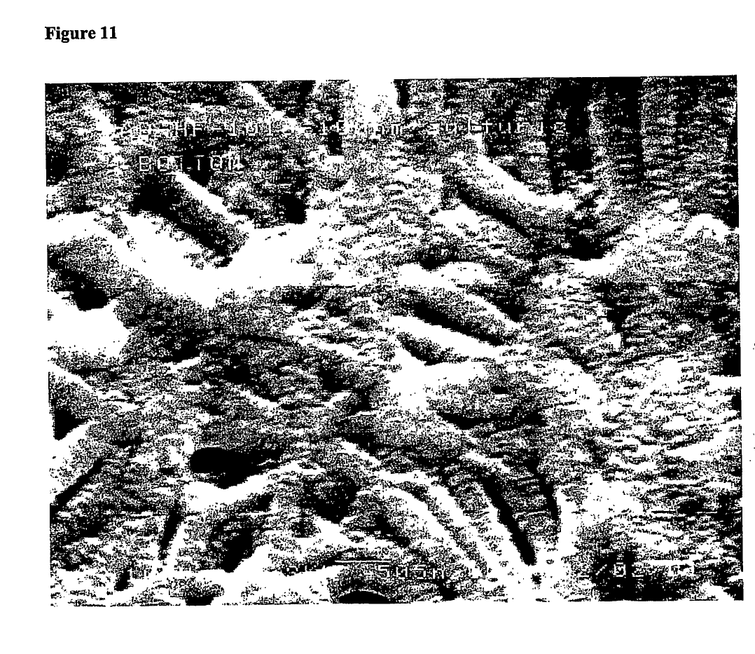

The composite HFCVD/PTFE membranes have been shown to be stable to an eighteen hour soak in 96% sulfuric acid. In fact, SEM images show that the HFCVD PTFE coating does not detach to a detectable extent from PTFE fibrils of the membrane under these conditions. See FIGS. 8-11. Moreover, the flow rate of water through the membranes does not appear to be influenced by soaking in concentrated sulfuric acid. For example, after soaking in concentrated sulfuric acid for five hours, water flowed through the PTFE membrane coated with a 100 nm layer of PTFE at a rate of 0.44 mL/s; whereas, the same membrane prior to soaking in concentrated sulfuric acid allowed water to flow at a rate of 0.49 mL/s.

Further, the relative flow rates of air through membranes of the present invention have been determined. Under a given set of conditions, the following air flow rates were measured: (1) PTFE membrane with 0.1 mm pores, 100 cc/35.00 s; (2) PTFE membrane with 0.1 mm pores, coated with a 20 nm layer of PTFE, 100 cc/44.78 s; (3) PTFE membrane with 0.1 mm pores, coated with a 100 nm layer of PTFE, 100 cc/56.68 s; and (4) PTFE membrane with 0.1 mm pores, coated with a 300 nm layer of PTFE, 100 cc/766.20 s.

Additionally, the composite membranes have surface energies, crystalline properties, and fluorine-to-carbon ratios comparable to native PTFE. These characteristics where tested by critical wet surface tension measurements (CWST), differential scanning calorimetry (DSC), and x-ray photoelectron spectroscopy (XPS), respectively.

Preferably, the precursor gas is hexafluoropropylene oxide, and the heat source preferably is a resistively-heated conducting filament suspended over the membrane surface or a heated plate having a pyrolysis surface that faces the structure. For the HFCVD coatings, undiluted hexafluoropropylene oxide (HFPO; CF₃CF(O)CF₂) was used as the precursor gas. Films were deposited onto circular sections of PTFE membranes affixed to 4″ diameter silicon wafers. The depositions were carried out in a custom built vacuum chamber using filament to substrate distance of 2.5 cm. K. K. S. Lau and K. K. Gleason, J. Fluorine Chem. 104, 119 (2001). HFCVD does not require heating of the substrate material and hence temperature sensitive materials, such as polymers, can readily be coated. The heat source temperature is preferably greater than about 400K and the membrane surface is preferably maintained at a temperature less than about 300K.

Fluorocarbon films deposited by HFCVD and possess a chemical structure similar to PTFE as determined by ¹⁹F nuclear magnetic resonance, fourier transform infrared spectroscopy, and C1s x-ray photoelectron spectroscopy. S. J. Limb, K. K. S. Lau, D. J. Edell, and K. K. Gleason, Plasmas and Polymers, 4, 21 (1999).

The morphology of the HFCVD coatings can be varied over a wide range and impact film density. K. K. S. Lau, J. A. Caulfield, and K. K. Gleason, Chem. Materials, 12, 3032 (2000). Substantial porosity (>30%) with submicron pore size can be introduced. J. B. Fenn et. al. Vacuum & Coating Technology, March 2001, pg. 56. Partial coverage of membranes with dense coatings is desirable for filtration of chemicals and solvents. Complete overcoating of the base membranes with a porous HFCVD membrane has the potential to create ultra-thin supported films for gas/liquid separations required in degasification and chemical generation. The HFCVD process can readily be scaled as large scale roll-to-roll vacuum coating processes are well known. J. B. Fenn et. al. Vacuum & Coating Technology, March 2001, pg. 56.

Definitions

For convenience, certain terms employed in the specification, examples, and appended claims are collected here.

The term “membrane” as used herein means any thin sheet of natural or synthetic material that is permeable to substances in solution or in gaseous form.

The term “PTFE” as used herein stands for polytetrafluoroethylene and refers to a polymer having a monomeric repeating unit of the following formula:

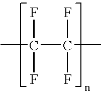

The term “ultrafine” as used herein refers to a membrane pore size where the maximum pore size is greater than or equal to about 0.02 μm.

The term “microporous” as used herein refers to a membrane pore size where the maximum pore size is less than about 0.02 μm.

The term “submicron” as used herein means less than one micron.

The term “copolymer” as used herein means a polymer of two or more different monomers.

The term “fluorocarbon” as used herein means a halocarbon compound in which fluorine replaces some or all hydrogen atoms.

The term “CVD” stands for “chemical vapor deposition,” and as used herein means a process which transforms gaseous molecules or radicals into solid material in the form of a thin film or powder on the surface of a substrate.

The term “HFCVD” stands for “hot filament chemical vapor deposition,” and as used herein means a process which transforms gaseous molecules or radicals at high temperatures into solid material in the form of a thin film or powder on the surface of a substrate.

The term “PECVD” stands for “plasma enhanced chemical vapor deposition,” and as used herein means a process which transforms gaseous molecules or radicals under electromagnetic irradiation into solid material in the form of a thin film or powder on the surface of a substrate.

The term “carbene” as used herein means a reactive intermediate that has the general formula R₂C:, in which carbon has only a sextet of electrons.

The abbreviation “HFPO” as used herein means “hexafluoropropylene oxide,” an epoxide of the formula CF₃CF(O)CF₂ and presented below.

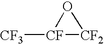

The term “biopassivation” as used herein means the property of a membrane surface that renders the membrane impervious to its biological environment.

For purposes of this invention, the chemical elements are identified in accordance with the Periodic Table of the Elements, CAS version, Handbook of Chemistry and Physics, 67th Ed., 1986-87, inside cover.

Film Structure

Notably, and in contrast to films deposited by PECVD, films deposited via hot-filament CVD (HFCVD) have well-defined compositions. For example, PECVD-deposited fluorocarbon films comprise a variety of CF groups (e.g., CF₃, tertiary C, and C—F, in addition to CF₂), while HFCVD-deposited fluorocarbon films consist almost entirely of CF₂, along with a small amount of CF₃ moieties. Further, the initiating and terminating groups in HFCVD are well-defined; whereas the precursors in PECVD processes undergo much greater fragmentation. A consequence of the nature of the HFCVD process is that only the most thermally stable groups (e.g., CF₂) appear in the film, resulting in more thermally stable films.

One of the most important specific chemical differences between hot-filament CVD and plasma-enhanced CVD is the occurrence of ion-bombardment and ultraviolet-irradiation in the latter technique. Due to this difference, HFCVD films do not contain defects seen in PECVD films. For example, HFCVD films do not have dangling bonds, which are always produced in PECVD processes. Dangling bonds are unpaired electrons left behind in the film. If such bonds are present, the film will undergo reactions with components of the ambient atmosphere (such as water, for instance, resulting in a large number of hydroxyl groups). Therefore, PECVD films are more susceptible to atmospheric ageing, and degradation of their optical, electrical and chemical properties. Moreover, films produced by HFCVD processes are less dense than those produced by plasma-enhanced CVD processes. Due to the differences between the nucleation and growth mechanisms the two processes, it is possible to make porous films using HFCVD, but not using PECVD. Porosity is an important property for semiconductor applications because it allows further lowering of the dielectric constant of existing low-κ materials by virtue of the low dielectric constant of air. Porosity is also an important property for filtration membranes especially in high performance applications. Additionally, a coating process to modify the geometric nature of the pore structure of a PTFE membrane by the deposition of additional PTFE has been discovered.

Film Properties

Biopassivation

Biopassivating coatings, i.e., coatings that insulate an article and render it impervious to its biological environment, are generating an increased amount of attention as many biomedical and other applications are not optimally addressed by available coatings in the art such as polytetrafluoroethylene, also known as PTFE, (CF₂)ₙ, and Teflon®, for example. Biologically-implantable devices such as neural probes, catheter inserts, implantable tubing, and other such devices, all of which are becoming increasingly complicated in geometry, are preferably encapsulated with a film to render the devices impervious to a biological environment, rather than being housed in a bulky PTFE package structure. Such implantable devices typically require of an encapsulating film not only the desired biological compatibility, but due to complex topology and connections to lead wires and associated circuitry, also inherently require an encapsulating film to be conformal and thin, as well as electrically insulating, tough, and flexible. Such a film should further be a good permeation barrier against the implantation environment.

Rigidity/Flexibility as a Factor of Crosslinking

The flexibility of the polymer coatings of the present invention makes them ideally suited for filtering applications. Coating rigidity/flexibility is a function of the amount of crosslinking between the polymer chains. HFCVD is advantageous over plasma enhanced chemical vapor deposition (PECVD) in this regard as fewer number of side reactive species capable of forming crosslinking bonds are formed during HFCVD. Further, lower filament temperature results in less crosslinking and therefore less rigidity and brittleness. The present invention, therefore, offers a way of tuning the degree of flexibility according to the application by adjusting the filament temperature.

The flexibility of the coatings of the present invention may be quantified using the technique of nano-indentation. This technique enables the measurement of the modulus and toughness of thin films.

Supercritical CO₂ Solubility

Processing used in microelectronics is increasingly designed with environmental impact in mind. As technologies change, new process insertion points occur. Super critical carbon dioxide (SCF CO₂) is a promising development medium for fluorocarbon polymer resists. Similar to other fluorine-containing materials, the fluorocarbon polymers prepared by HFCVD techniques are insoluble in aqueous developers. Performance enhancement is possible with SCF CO₂ due to the unique properties of the supercritical phase, including low viscosity, negligible surface tension, high diffusivity relative to the gas phase, and a density similar to that of the liquid phase. The solvating capability of SCF CO₂ towards the fluorocarbon polymer films can be fine-tuned by temperature and pressure control. We have found SCF CO₂ suitable as a developer for HFCVD fluorocarbon systems, as well as for fluorinated resists patterned with small and high aspect ratio features that may otherwise experience pattern collapse due to surface tension from aqueous developers. Combined, HFCVD film formation and dry development present a unique processing combination with impressive environmental and safety advantages over current solvent-based spin-on coating and aqueous development. Solvent -based technologies typically generate large quantities of liquid waste that is hazardous and costly to dispose of. HFCVD techniques generate only gaseous effluent and CVD chemistries can be designed to minimize the toxicity of this effluent. CO₂ is non-toxic, non-flammable, recyclable material that is typically collected from waste-streams of other synthetic processes and is available at a low cost with no waste generation.

Exemplary Halocarbon Monomers

A halocarbon monomer used in a method of the present invention may be selected from the group of suitable halocarbons. For example, the halocarbon monomer used may be hexafluoropropylene oxide, tetrafluoroethylene, hexafluorocyclopropane, octafluorocyclobutane, perfluorooctanesulfonyl fluoride, octafluoropropane, trifluoromethane, difluoromethane, difluorodichloromethane, difluorodibromomethane, difluorobromomethane, difluorochloromethane, trifluorochloromethane, tetrafluorocyclopropane, tetrachlorodifluorocyclopropane, trichlorotrifluoroethane, or dichlorotetrafluorocyclopropane.

Exemplification

The invention now being generally described, it will be more readily understood by reference to the following examples, which are included merely for purposes of illustration of certain aspects and embodiments of the present invention, and are not intended to limit the invention.

General Spectroscopic Methods

Fourier-transform infrared (FTIR) spectroscopy was performed on the deposited films using a Nicolet Magna 860 spectrometer in transmission mode. The spectra were baseline corrected and normalized to a thickness of approximately 7000 Å. X-ray photoelectron spectroscopy (XPS) was carried out on a Kratos Axis Ultra spectrometer using a monochromatized aluminum K-α source.

Solid-state NMR spectroscopy was performed on a homebuilt spectrometer comprising a 6.338 T Oxford superconducting magnet and a 3.2 mm Chemagnetics magic angle sample spinning (MAS) probe. For this analysis, approximately 14 mg of film was scraped off wafers from nine 30-min depositions, and packed into a zirconia rotor of 11 mm³ internal volume. Sample spinning at the magic angle of 54.7° was performed in order to mitigate spectral broadening due to strong homonuclear dipolar and anisotropic chemical shift effects. The sample spinning speeds were 5 kHz, 25 kHz and 10 kHz for ²⁹Si, ¹⁹F and ¹³C respectively.

¹⁹F NMR spectra were obtained by direct polarization with a 90° pulse width of 1.2 μs. Chemical shifts were externally referenced to trichlorofluoromethane. ¹³C spectra were obtained by direct polarization with proton decoupling as well as direct polarization with fluorine decoupling. The 90° pulse width was 1.8 μs for both types of spectra. ¹³C chemical shifts were externally referenced to tetramethylsilane.

Deposition Methods

Start Up Procedure

Prior to each experiment, the interior of the deposition chamber was cleaned thoroughly with paper towels and Scotch Brite soaked in acetone or isopropanol. The filament wire was then strung onto the holder, and the holder was placed inside the reactor and connected to the power supply. The chamber was then evacuated.

Depositing the Polymer Film

Depositions were performed in a custom-built vacuum chamber on to porous PTFE membranes. Pressure within the chamber was controlled by a butterfly valve connected to a PI controller. Substrates were placed on a stage maintained at a low temperature (15±5° C.) by the circulation of chilled water through internal coils. Precursor breakdown was achieved by means of a resistively heated nichrome (80% nickel, 20% chromium; Omega Engineering) wire 0.038 cm in diameter. The frame holding the filament wire was equipped with springs to compensate for thermal expansion of the wire upon heating. The distance between the filament wire and the substrate was 1.4 cm. Filament temperature was measured by a 2.2 μm infrared pyrometer. The spectral emissivity was estimated to be 0.85 based on direct contact thermocouple experiments.

The flow of fluorocarbon precursor, hexafluoropropylene oxide gas (HFPO), into the chamber was controlled by an MKS Model 1295C Mass Flow Controller (MFC). The lines leading from the vessel to the vacuum chamber were maintained at 130±5° C. Flow of vapor from the vessel into the chamber was regulated by a needle valve.

For the HFCVD coatings, undiluted hexafluoropropylene oxide (HFPO; CF₃CF(O)CF₂) was used as the precursor gas. Films were deposited onto circular sections of PTFE membranes affixed to 4″ diameter silicon wafers. The depositions were carried out in a custom built vacuum chamber using filament to substrate distance of 2.5 cm. K. K. S. Lau and K. K. Gleason, J. Fluorine Chem. 104, 119 (2001). HFCVD does not require heating of the substrate material and hence temperature sensitive materials, such as polymers, can readily be coated.

Shut Down Procedure

The filament power was turned down rapidly (in less than 10 sec) with the precursors still flowing. The HFPO valve was then closed. Chamber was then evacuated to base pressure, and then pumped up to atmospheric pressure.

### INCORPORATION BY REFERENCE

All of the patents and publications cited herein are hereby incorporated by reference.

Equivalents

Those skilled in the art will recognize, or be able to ascertain using no more than routine experimentation, many equivalents to the specific embodiments of the invention described herein. Such equivalents are intended to be encompassed by the following claims.

1. A method for forming a polytetrafluoroethylene (PTFE) thin film on one side of a PTFE membrane, comprising the steps of:
exposing a monomer fluorocarbon gas to a source of heat having a temperature sufficient to pyrolyze the monomer gas, the monomer gas selected to produce upon pyrolysis sources of reactive species that consist essentially of polymerizable CF₂ species and that selectively promote polymerization, the reactive species source being in the vicinity of one side of a PTFE membrane on which a PTFE film is to be formed; and
maintaining the PTFE membrane at a substantially lower temperature than that of the heat source to induce deposition and polymerization of the CF₂ reactive species on the PTFE membrane.

2. The method of claim 1, wherein the fluorocarbon is selected from the group consisting of hexafluoropropylene oxide, tetrafluoroethylene, hexafluorocyclopropane, octafluorocyclobutane, perfluorooctanesulfonyl fluoride, octafluoropropane, trifluoromethane, difluoromethane, difluorodichloromethane, difluorodibromomethane, difluorobromomethane, difluorochloromethane, trifluorochloromethane, tetrafluorocyclopropane, tetrachlorodifluorocyclopropane, trichlorotrifluoroethane, and dichlorotetrafluorocyclopropane.

3. The method of claim 2, wherein the fluorocarbon is hexafluoropropylene oxide.

4. The method of claim 1, wherein the heat source to which the monomer gas is exposed comprises a resistively-heated conducting filament suspended above the PTFE membrane.

5. The method of claim 1, wherein the heat source to which the monomer gas is exposed comprises a heated plate having a pyrolysis surface that faces the PTFE membrane.

6. The method of either claim 4 or 5, wherein the heat source temperature is greater than about 400 K; and the step of maintaining the membrane temperature comprises maintaining the membrane at a temperature less than about 300 K.

7. A modified PTFE membrane having on one side a PTFE thin film having a porosity greater than about 30%; and wherein the PTFE thin film has a dangling bond density less than about 10¹⁸ spins/cm³.

8. A method of filtering a liquid, gas, or mixture of a liquid and gas, comprising:
passing the liquid, gas, or mixture of a liquid and gas through the modified PTFE membrane of claim 7 at a pressure sufficient to facilitate passage of the liquid, gas, or mixture of a liquid and gas.
